(19) United States
(12) Patent Application Publication
(10) Pub. No.: US 2026/0344490 A1
(43) Pub. Date: Oct. 29, 2026

(54) ELECTRONIC COMPONENT MOUNTING METHOD AND ELECTRONIC COMPONENT MOUNTING SYSTEM

(71) Applicant: TORAY ENGINEERING CO., LTD., Tokyo (JP)

(72) Inventors: Takayuki MIYOSHI, Toyota-shi (JP); Takashi HARE, Takatsuki-shi (JP); Toyoharu TERADA, Otsu-shi (JP); Jun MIZUNO, Tainan City (TW)

(21) Appl. No.: 19/705,385

(22) Filed: Jun. 11, 2026

Related U.S. Application Data
(63) Continuation of application No. PCT/JP2024/043479, filed on Dec. 9, 2024.

(30) Foreign Application Priority Data
Dec. 21, 2023 (JP) 2023-216231
Oct. 24, 2024 (JP) 2024-187700

(51) Int. Cl. H10W 72/00

(52) U.S. Cl. CPC H10W 72/07211; H10W 72/07232

(57) ABSTRACT

An electronic component mounting method for bonding a bump formed on a first electrode of a first electronic component to a second electrode formed on a second electronic component includes etching the first electronic component and the second electronic component using a weakly acidic organic acid to remove an oxide film formed on surfaces of the second electrode and the bump, bonding the bump formed on the first electrode to the second electrode in a state in which the first electronic component and the second electronic component are accommodated in a bonding device after the etching, and inert gas is supplied to the bonding device.

### CROSS REFERENCES TO RELATED APPLICATIONS

This application is a continuation application of PCT International Application No. PCT/JP2024/043479 filed on Dec. 9, 2024. This application claims priority to Japanese Patent Application Nos. 2023-216231 filed on Dec. 21, 2023 and 2024-187700 filed on Oct. 24, 2024 with Japan Patent Office. The entire disclosures of PCT International Application No. PCT/JP2024/043479 and Japanese Patent Application Nos. 2023-216231 and 2024-187700 are hereby incorporated herein by reference.

### BACKGROUND

### Field of the Invention

The present invention generally relates to a mounting method and a mounting system of electronic components in which electrodes of electronic components are bonded to each other via bumps.

### Background Information

For example, when bonding a bump formed on an electrode of an electronic component, such as a semiconductor chip, to a connection terminal of a wiring substrate, if an oxide film is formed on the surface of the bump or the connection terminal of the wiring substrate, the bond between the bump and the electrode is inhibited, causing connection failure. Therefore, a method of bonding a bump to an electrode of a wiring substrate in a state in which flux is applied to the surface of the wiring substrate is commonly carried out. As a result, bonding is carried out in a state in which the oxide film formed on the surfaces of bumps and electrodes has been removed by the flux.

However, as bump pitch narrows, it becomes difficult to sufficiently remove the flux. Flux residue may generate migration and corrosion of wiring. Therefore, flux-less bonding methods are being evaluated as methods that eliminate the effects of flux residue.

For example, Japanese Laid-Open Patent Application Publication No. 2001-244618 (Patent Document 1) discloses a method in which bumps formed on electrodes of an electronic component are caused to reflow (fusion bonding) onto connection terminals of the wiring substrate while supplying gas of a carboxylic acid such as formic acid into a heat fusion treatment apparatus (bonder). This method allows the oxide film formed on the surfaces of bumps and connection terminals to be removed by the reduction action of the carboxylic acid gas.

### SUMMARY

In the method disclosed in Patent Document 1, the gas of a carboxylic acid such as formic acid introduced into the heat fusion treatment apparatus (bonder) is corrosive, so that it is necessary to take sufficient anti-corrosion measures inside the heat fusion treatment apparatus. However, since a heat fusion treatment apparatus has a complex structure including a transport mechanism, an alignment mechanism, and a pressurizing and heating mechanism, which requires extensive anti-corrosion measures, leading to an increase in equipment costs.

In addition, in the method described above, the carboxylic acid gas introduced into the bonder is exhausted and removed from the apparatus after the reduction of the oxide film is completed; however, there is the risk that carboxylic acid salt (organic compound) of the metal constituting the bumps or the connection terminals generated during the reduction process of the oxide film is not decomposed and a part of the carboxylic acid salt remains as residue on the electronic component or the wiring substrate. In that case, since carboxylic acid salt has high insulating properties, there is the problem that a highly-reliable bond cannot be obtained.

In addition, in the method described above, it is necessary to carry out the oxide film reduction process while controlling the temperature inside the bonder to be within a range of greater than or equal to the reduction temperature of the oxide film on the bumps by the carboxylic acid gas and less than the melting temperature of the bumps; however, the amount of evaporation of the carboxylic acid gas fluctuates with the ambient temperature, so that there is a problem that it is difficult to control the concentration of the carboxylic acid gas.

One object of the present disclosure is to provide an electronic component mounting method and an electronic component mounting system with which it is possible to achieve highly-reliable fluxless bonding with a simple device.

An electronic component mounting method according to the present disclosure is an electronic component mounting method for bonding a bump formed on a first electrode of a first electronic component to a second electrode formed on a second electronic component, the method comprising etching the first electronic component and the second electronic component using a weakly acidic organic acid to remove an oxide film formed on surfaces of the bump and the second electrode, and bonding the bump formed on the first electrode of the first electronic component to the second electrode formed on the second electronic component in a state in which the first electronic component and the second electronic component are accommodated in a bonding device after the etching, and inert gas is supplied to the bonding device.

An electronic component mounting system according to the present disclosure is an electronic component mounting system for bonding a bump formed on a first electrode of a first electronic component to a second electrode formed on a second electronic component, the system comprising an etching device configured to etch the first electronic component and the second electronic component using a weakly acidic organic acid to remove an oxide film formed on surfaces of the bump and the second electrode, and a bonding device configured to accommodate the first electronic component and the second electronic component that have been etched in the etching device, and configured to bond the bump formed on the first electrode of the first electronic component to the second electrode formed on the second electronic component in a state in which inert gas is supplied.

Another electronic component mounting method according to the present disclosure is an electronic component mounting method for bonding a bump formed on a first electrode of a first electronic component to a second electrode formed on a second electronic component, the method comprising etching the second electronic component using a weakly acidic organic acid to remove an oxide film formed on a surface of the second electrode, accommodating the first electronic component and the second electronic component in a bonding device after the etching, and bonding the bump formed on the first electrode of the first electronic component to the second electrode formed on the second electronic component in a state in which inert gas is supplied to the bonding device, the bonding being carried out by bringing the bump formed on the first electrode into contact with the second electrode, and then, in a state in which the bump is in a molten state, applying to the first electronic component or the second electronic component vibration that causes relative displacement in a direction parallel to an interface between the bump and the second electrode.

According to the present disclosure, it is possible to provide an electronic component mounting method and an electronic component mounting system with which it is possible to achieve highly-reliable fluxless bonding with a simple device.

### BRIEF DESCRIPTION OF THE DRAWINGS

FIG. 1A is a cross-section diagram schematically showing a step of an electronic component mounting method according to a first embodiment of the present disclosure.

FIG. 1B is a cross-section diagram schematically showing a step of the electronic component mounting method according to the first embodiment of the present disclosure.

FIG. 1C is a cross-section diagram schematically showing a step of the electronic component mounting method according to the first embodiment of the present disclosure.

FIG. 1D is a cross-section diagram schematically showing a step of the electronic component mounting method according to the first embodiment of the present disclosure.

FIG. 2 is a cross-section diagram schematically showing a step of an electronic component mounting method according to another embodiment.

FIG. 3 is a diagram explaining a step for bonding a bump according to a second embodiment of the present disclosure.

FIG. 4 is a diagram explaining a step for bonding a bump according to a second embodiment of the present disclosure.

FIG. 5A is a cross-sectional SEM photograph of the bonding portion of a bump in sample A.

FIG. 5B is a cross-sectional SEM photograph of the bonding portion of a bump in sample B.

FIG. 6 is a diagram explaining a bump bonding step according to a third embodiment of the present disclosure.

FIG. 7 is a cross-sectional SEM photograph of a bonding portion of a bump according to the third embodiment of the present disclosure.

FIG. 8 is a cross-section diagram schematically showing a configuration of an electronic component mounting system according to one embodiment of the present disclosure.

FIG. 9 is a cross-section diagram schematically showing another configuration of the bonding device.

FIG. 10 is a cross-section diagram schematically showing another configuration of the bonding device.

FIG. 11 is a cross-section diagram schematically showing a configuration of an electronic component mounting system according to another embodiment.

### DETAILED DESCRIPTION OF EMBODIMENTS

### First Embodiment

The present disclosure relates to an electronic component mounting method for bonding a bump formed on a first electrode of a first electronic component to an electrode formed on a second electrode of a second electronic component. Here, the first electronic component and the second electronic component include semiconductor chips, ball grid array (BGA) packages, printed circuit boards, interposers, electronic component mounting boards, and the like. In addition, bumps include high-melting-point metals such as copper and gold, low-melting-point metals such as solder bumps, and bumps formed of other metals. In addition, the first electrode and the second electrode include metals such as copper, gold, and nickel.

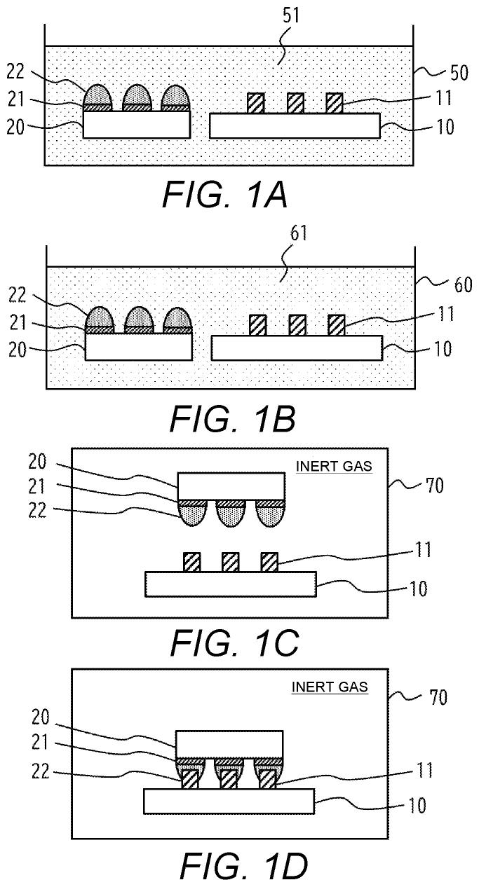

FIGS. 1A to 1D are cross-section diagrams schematically showing steps of the electronic component mounting method according to the first embodiment. In the first embodiment, an example will be described in which bumps formed on electrodes (first electrode) of a semiconductor chip (first electronic component) are fusion-bonded (hereinbelow sometimes referred to as “bump bonding”) to connection terminals (second electrode) of a printed circuit board (second electronic component). The semiconductor chip may be a plurality of semiconductor chips diced in a wafer state.

First, as shown in FIG. 1A, a semiconductor chip 20 and a printed circuit board 10 are immersed in an aqueous solution (hereinafter referred to as “aqueous citric acid solution”) 51 containing citric acid in an etching tank (etching device). Here, a plurality of electrodes 21 are formed on the surface of the semiconductor chip 20, and a bump 22 is formed on each of the electrodes 21. In addition, connection terminals 11 are formed on the surface of the printed circuit board 10.

Citric acid has the property of dissolving oxides of metals such as copper. For example, copper oxide (CuO) dissolves in aqueous citric acid (C6H8O7) solution according to the following reaction formula.

3CuO+2C6H8O7→Cu3(C6H8O7)2+H2O

Accordingly, by immersing the semiconductor chip 20 and the printed circuit board 10 in the aqueous citric acid solution 51, the oxide film (hereinafter referred to as “metal oxide film”) formed on the surfaces of the bumps 22 and the connection terminals 11 is etched off by the aqueous citric acid solution 51.

Here, the concentration of the citric acid is preferably 0.1 mass % or more and 10 mass % or less. If the concentration of the citric acid is less than 0.1 mass %, the etching rate of the metal oxide film becomes slow, which is not preferable. In addition, if the concentration of the citric acid exceeds 10 mass %, citric acid crystals may precipitate into the aqueous citric acid solution, or the surface roughness of the treated metal oxide film may deteriorate, which is not preferable.

In addition, the temperature of the aqueous citric acid solution is preferably in the range of 20 °C or more and 90 °C or less. In particular, the etching rate of the metal oxide film can be increased by raising the temperature of the aqueous citric acid solution to 40 °C or more.

Since citric acid is weakly acidic and thus easy to handle, the etching device is able to carry out etching of the metal oxide film simply by preparing an etching tank 50 containing an aqueous citric acid solution. As a result, it is possible to remove metal oxide film using a simpler etching device, compared to conventional reduction processes of metal oxide film using carboxylic acid gas. Thus, in the illustrated embodiment, the etching device includes the etching tank 50.

In addition, because etching of metal oxide film is carried out using weakly acidic aqueous citric acid solution, it is possible to prevent corrosion of the substrate during etching even if the substrate is composed of resin with poor acid resistance.

In the first embodiment, the removal of metal oxide film is carried out by immersing the semiconductor chip 20 and the printed circuit board 10 in an aqueous citric acid solution, but the removal can be carried out by spraying the aqueous citric acid solution as a mist on the surfaces of the semiconductor chip 20 and the printed circuit board 10. In this case, the etching device includes a sprayer.

The etching material used for removing the metal oxide film is not particularly limited as long as the material exhibits an etching action on oxide film of the bumps 22 and connection terminals 11, and weakly acidic organic acids with a pH of 2 to 6 can be used such as acetic acid, tartaric acid, malonic acid, succinic acid, and adipic acid, in addition to citric acid. In addition, the etching material may be a mixture of these organic acids.

Next, as shown in FIG. 1B, the semiconductor chip 20 and the printed circuit board 10 that have been etched with an aqueous citric acid solution are immersed in purified water 61 in a cleaning tank 60, and the surfaces of the semiconductor chip 20 and the printed circuit board 10 are cleaned under running water by a well-known method.

The semiconductor chip 20 and the printed circuit board 10 are preferably transported to the cleaning tank 60 in an atmosphere of inert gas, such as nitrogen, while being transported from the etching tank 50 to the cleaning tank 60 so that the surfaces of the bumps 22 and the connection terminals 11 are not re-oxidized. In addition, an ultrasonic cleaning device or cleaner may be used to clean the semiconductor chip 20 and the printed circuit board 10.

After being cleaned, the semiconductor chip 20 and the printed circuit board 10 are dried using a well-known method (not shown). The drying process is preferably carried out under an atmosphere of inert gas such as nitrogen inside a drying chamber so that the surfaces of the bumps 22 and the connection terminals 11 are not re-oxidized. In addition, drying by applying heat from the outside promotes oxidation of the surfaces of the bumps 22 and the connection terminals 11, and thus is not preferable.

Next, as shown in FIG. 1C, the semiconductor chip 20 and the printed circuit board 10 that have been cleaned and dried are placed in a bonding device (flip-chip bonder) 70, and the bumps 22 formed on the electrodes 21 of the semiconductor chip 20 are positioned facing the connection terminals 11 of the printed circuit board 10. The configurations of the flip-chip bonder can be conventional, and will not be described in detail for the sake of brevity. In the illustrated embodiment, the bonding device 70 has a processing chamber in which the semiconductor chip 20 and the printed circuit board 10 are accommodated and a bonding step for bonding the bumps 22 to the connection terminals 11 is carried out.

Then, as shown in FIG. 1D, after bringing the bumps 22 into contact with the connection terminals 11 of the printed circuit board 10, the semiconductor chip 20 is heated to fusion-bond the bumps 22 formed on the electrodes 21 of the semiconductor chip 20 to the connection terminals 11 of the printed circuit board 10, in a state in which the bumps 22 are molten (the bonding step).

In the bonding step described above, the interior of the bonding device 70 (the interior of the processing chamber of the bonding device 70) is preferably kept in an atmosphere of inert gas such as nitrogen such that the surfaces of the bumps 22 and the connection terminals 11 are not re-oxidized.

In addition, the semiconductor chip 20 and the printed circuit board 10 that have been cleaned and dried are preferably transported to the bonding device 70 in an atmosphere of inert gas such as nitrogen, so that the surfaces of the bumps 22 and the connection terminals 11 are not re-oxidized during transport.

According to the electronic component mounting method according to the first embodiment, the semiconductor chip (first electronic component) 20 and the printed circuit board (second electronic component) 10 are etched with a weakly acidic organic acid such as citric acid before carrying out the bonding step for bonding bumps 22 formed on the electrodes 21 of the semiconductor chip 20 to the connection terminals 11 of the printed circuit board 10 to remove oxide film (metal oxide film) formed on the surfaces of the bumps 22 and the connection terminals 11, thereby making it possible to carry out bump bonding in a state in which the oxide film formed on the surfaces of the bumps 22 and the connection terminals 11 is removed.

The etching of the metal oxide film in the first embodiment uses a weakly acidic organic acid; therefore, handling is easy, and it is not necessary to take measures against corrosion from carboxylic acid gas or against residues of carboxylic acid salt, so that it is possible to obtain highly-reliable fluxless bump bonding with a simple device, compared to conventional reduction processes of metal oxide film using carboxylic acid gas.

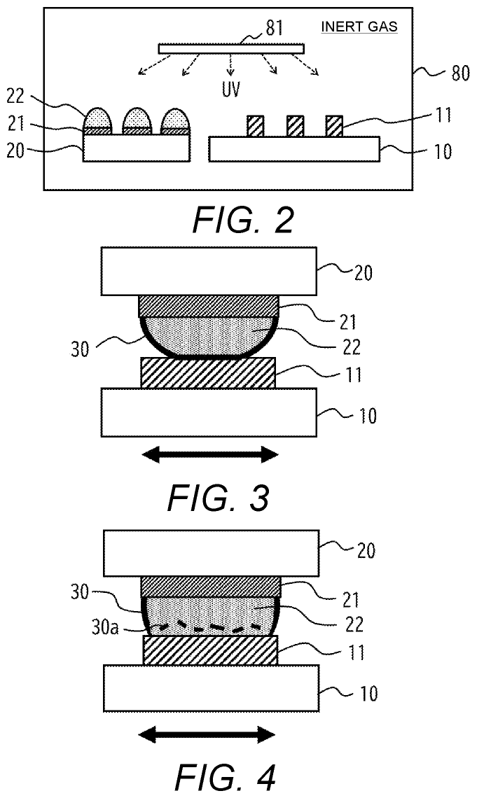

In the first embodiment, as shown in FIG. 2, an irradiation step may be carried out in which the semiconductor chip 20 and the printed circuit board 10 are accommodated in an ultraviolet irradiation device 80 (e.g., an irradiation device), and the surfaces of the semiconductor chip 20 and the printed circuit board 10 are irradiated with ultraviolet rays (UV) from an ultraviolet light source 81. Thus, in the illustrated embodiment, the irradiation device includes the ultraviolet irradiation device 80 with the ultraviolet light source 81.

During the manufacturing steps of the semiconductor chip 20 and the printed circuit board 10, there are cases in which unnecessary contaminants are adhered to the surfaces of the semiconductor chip 20 and the printed circuit board 10. If a contaminant is adhered to the surface, there is the risk that the metal oxide film cannot be sufficiently removed in the etching step of the metal oxide film. In addition, there is the risk that the contaminant enters the aqueous citric acid solution and contaminates the aqueous citric acid solution.

Therefore, it is preferable to irradiate the surfaces of the semiconductor chip 20 and the printed circuit board 10 with ultraviolet rays before the etching step to remove, in advance, contaminants adhered to the surfaces of the semiconductor chip 20 and the printed circuit board 10. It is thereby possible to remove the metal oxide film in a short period of time in the etching step of the metal oxide film to keep the aqueous citric acid solution clean.

Here, in the UV irradiation step, it is preferable to carry out UV irradiation in a state in which inert gas such as nitrogen (N2) is supplied (inert gas atmosphere) to the ultraviolet irradiation device 80 so that the surfaces of the bumps 22 and the connection terminals 11 are not oxidized. In the illustrated embodiment, the ultraviolet irradiation device 80 has a processing chamber in which the semiconductor chip 20 and the printed circuit board 10 are accommodated and the UV irradiation step is carried out.

In addition, while the wavelength of the ultraviolet rays is not particularly limited, it is more preferable to use vacuum ultraviolet rays with a short wavelength and high energy (wavelength of less than or equal to 200 nm). In addition, a mercury lamp, an excimer lamp, a plasma UV lamp, etc., can be used as an ultraviolet light source 62. In addition, instead of irradiating ultraviolet rays, the surfaces of the semiconductor chip 20 and the printed circuit board 10 may be irradiated with plasma. In this case, the irradiation device includes a plasma treatment device.

In addition, in the bonding step of the first embodiment, instead of carrying out bonding in an atmosphere of inert gas such as nitrogen inside the bonding device 70 such that the surfaces of the bumps 22 and the connection terminals 11 are not re-oxidized, the bonding may be carried out in a state in which inert gas is supplied around the semiconductor chip 20 and the printed circuit board 10 in the bonding device 70.

In addition, the etching step in the first embodiment may be executed inside the bonding device 70. In this case, the etching step and the bonding step are preferably carried out in a state in which the bonding device 70 is filled with inert gas.

### Second Embodiment

In the above-mentioned first embodiment, the semiconductor chip 20 and the printed circuit board 10 are etched with a weakly acidic organic acid such as citric acid to remove oxide film formed on the surfaces of the bumps 22 and the connection terminals 11, thereby making it possible to carry out bump bonding in a state in which the oxide film formed on the surfaces of the bumps 22 and the connection terminals 11 is removed.

However, for example, if solder is used as the material of the bumps 22 and copper is used as the material of the connection terminals 11, there may be cases in which removal of the oxide film formed on the surfaces of the bumps 22 takes longer that the removal of the oxide film formed on the surfaces of the connection terminals 11 in the etching process using citric acid, etc. Therefore, there may be cases in which variation in the film thickness of the oxide film formed on the surfaces of the bumps 22, variation in the concentration of the etching solution such as citric acid, or the like, may cause insufficient removal of the oxide film formed on the surfaces of the bumps 22. As a result, if fusion bonding is carried out while removal of the oxide film is insufficient, there is the risk of causing variation in bonding resistance.

As a countermeasure of the foregoing, a method in which fusion bonding is carried out while the distance between the electrodes 21 of the semiconductor chip 20 and the connection terminals 11 of the printed circuit board 10 is controlled to be less than the height of the bump 22. In this method, the molten bumps 22 are greatly deformed by the pressing force from the semiconductor chip 20 and the printed circuit board 10, whereby the oxide film formed on the surfaces of the bumps 22 is broken and the true surfaces of the bumps 22 are exposed. As a result, intermetallic compounds are formed at the interface between the connection terminals 11 and the bumps 22 that have wrapped around to the side surfaces of the connection terminals 11, thereby reducing variation in bonding resistance.

However, in the method described above, the molten bumps 22 wrap around the side surfaces of the connection terminals 11, so that as the bump 22 pitch narrows, there is the risk that a short-circuit occurs between the adjacent connection terminals 11. Therefore, in order to accommodate narrowing of the bump 22 pitch, it is necessary to carry out fusion bonding while controlling the distance between the electrodes of the semiconductor chip 20 and the connection terminals 11 of the printed circuit board 10 such that the molten bumps 22 do now wrap around to the side surfaces of the connection terminals 11.

Therefore, in the second embodiment, as shown in FIG. 3, in the bump 22 bonding step, the bumps 22 formed on the electrodes 21 of the semiconductor chip 20 (in a state in which an oxide film 30 remains on the surface) are brought into contact with the connection terminals 11 of the printed circuit board 10, and then, in a state in which the bumps 22 are molten, vibration is applied to the printed circuit board 10 that causes relative displacement in a direction parallel to the interface between the bumps 22 and the connection terminals 11.

Here, in the bump 22 bonding step, in order to prevent the molten bumps 22 from wrapping around to the side surfaces of the connection terminals 11, the vibration that is applied to the semiconductor chip 20 is preferably carried out while controlling the distance between the electrodes 21 of the semiconductor chip 20 and the connection terminals 11 of the printed circuit board 10 such that pressing force from the semiconductor chip 20 and the printed circuit board 10 is not applied to the molten bumps 22.

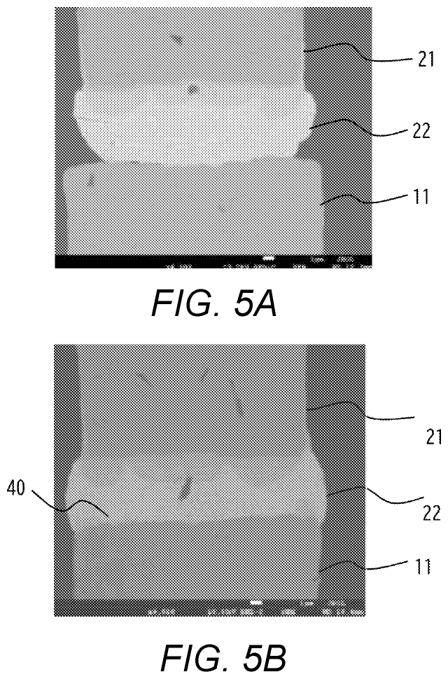

By carrying out the bump 22 bonding step in this manner, as shown in FIG. 4, the vibration applied to the printed circuit board 10 causes the molten bump 22 to flow, and the oxide film 30 remaining on the surface of the bump 22 that is in contact with the connection terminal 11 is broken by the flow pressure of the bump 22, exposing the true surface of the bump 22. As a result, an intermetallic compound is formed at the interface between the bump 22 and the connection terminal 11. As a result, even if the removal of oxide film formed on the surfaces of the bumps 22 is insufficient in the etching process using citric acid, etc., it is possible to reduce variation in the bonding resistance.

Note that the vibration may be applied to the semiconductor chip 20. In addition, the vibration applied to the printed circuit board 10 or the semiconductor chip 20 may be generated by controlling, with a servo motor, a stage on which the printed circuit board 10 is placed or a mounting head that holds the semiconductor chip 20. In addition, the vibration applied to the printed circuit board 10 or the semiconductor chip 20 may be generated separately in directions perpendicular to each other, at the interface between the bump 22 and the connection terminal 11. Thus, in the illustrated embodiment, the bonding device includes a processing chamber in which the semiconductor chip 20 and the printed circuit board 10 are accommodated and a bonding step for bonding the bumps 22 to the connection terminals 11 is carried out, a stage disposed within the processing chamber and on which the printed circuit board 10 is placed, a mounting head disposed within the processing chamber and holding the semiconductor chip 20, an application unit or vibrator having a servo motor to generate the vibration applied to the printed circuit board 10 (the stage) or the semiconductor chip 20 (the mounting head), and an electronic controller operatively coupled to various components of the bonding device, such as the stage (an electronic actuator of the stage to change the height or position of the stage), the mounting head (an electronic actuator of the mounting head to change the height or position of the mounting head), the application unit (the servo motor), etc., to carry out the bonding step. The controller is configured by a general-purpose computer device, for example, and includes at least one processor having a CPU (Central Processing Unit) and a storage device or computer memory, and an interface for each device is included, as necessary. Thus, the operations of the bonding device for the bonding step described below are controlled and executed by the controller.

In the second embodiment, the frequency of the vibration applied to the printed circuit board 10 or the semiconductor chip 20 is preferably in the range of 1/20 Hz to 50 Hz, and more preferably in the range of ⅕ Hz to 10 Hz. If the frequency is less than 1/20 Hz, the bump 22 bonding step becomes longer, which increases production costs and is thus not preferable. In addition, if the frequency exceeds 50 Hz, the vibration applied to the printed circuit board 10 or the semiconductor chip 20 becomes less able to follow the control by the servo motor and is thus not preferable.

The amplitude of the vibration applied to the printed circuit board 10 or the semiconductor chip 20 is preferably in the range of 1/20 or more, and more preferably in the range of 1/10 or more, of the width of the bump 22. If the amplitude of the vibration is less than 1/20 of the width of the bump 22, the flow pressure of the bump 22 that acts on the oxide film 30 remaining on the surface of the bump 22 becomes weak, making it less likely for the oxide film 30 to break, which is not preferable. In addition, the amplitude is preferably within a range of not coming into contact with the adjacent bumps 22.

In addition, in the case that vibration is applied to the printed circuit board 10 or the semiconductor chip 20 in the bump 22 bonding step, the etching process using citric acid, etc. carried out as preprocessing before the bonding step may be carried out on only the printed circuit board on which the bumps 22 are not formed. In this case, the oxide film formed on the surfaces of the connection terminals 11 is removed in the etching step, and the oxide film formed on the surfaces of the bumps 22 is removed in the bonding step that is carried out while applying vibration to the printed circuit board 10 or the semiconductor chip 20.

### <Effect of Vibration Application>

The following samples A to C were prepared to confirm the effects of applying vibration.

### (Sample A)

The semiconductor chip 20 and the printed circuit board 10 were etched using citric acid, after which bumps (solder) 22 formed on the electrodes (copper) 21 of the semiconductor chip 20 were fusion-bonded to the connection terminals (copper) 11 formed on the printed circuit board 10, without applying vibration to the printed circuit board 10.

### (Sample B)

The semiconductor chip 20 and the printed circuit board 10 were etched using citric acid, after which bumps (solder) 10 formed on the electrodes (copper) 21 of the semiconductor chip 20 were fusion-bonded to the connection terminals (copper) 10 formed on the printed circuit board 11, while applying vibration to the printed circuit board 10.

### (Sample C)

The bumps (solder) 22 formed on the electrodes (copper) 21 of the semiconductor chip 20 were fusion-bonded to connection terminals (copper) 11 formed on the printed circuit board 10, using a conventional flux method.

Table 1 is a table showing the results of measuring interfacial resistance between the bumps 22 and connection terminals 11 for each of the samples A to C. The interfacial resistance was measured by a two-terminal method using a tester.

TABLE 1

| | | | Vibration | Interfacial |
|---|---|---|---|---|
| | Flux | Citric acid | application | resistance |
| | method | treatment | (2 Hz) | (Ω) |
| Sample A | — | ∘ | — | 17.1-86.0 |
| Sample B | — | ∘ | ∘ | 17.4-18.9 |
| Sample C | ∘ | — | — | 17.1-18.4 |

As shown in Table 1, sample A in which the bumps 22 were fusion-bonded to the connection terminals 11 without applying vibration to the printed circuit board 10 showed great variability in the interfacial resistance.

In contrast, sample B in which the bumps 22 were fusion-bonded to the connection terminals 11 while applying vibration to the printed circuit board 10 showed a similar variability in the interfacial resistance as sample C in which the bumps 22 were fusion-bonded to the connection terminals 11 using the conventional flux method.

In addition, FIG. 5A is a cross-sectional SEM photograph of the bonding portion of a bump in sample A, and FIG. 5B is a cross-sectional SEM photograph of the bonding portion of a bump in sample B.

As shown in FIG. 5A, in sample A, it can be seen that the molten bump 22 has not wetted and spread over the surface of the connection terminal 11, and that an intermetallic alloy is not formed at the interface between the bump 22 and the connection terminal 11.

On the other hand, as shown in FIG. 5B, in sample B, it can be seen that the molten bump 22 has wetted and spread over the surface of the connection terminal 11, and that an intermetallic alloy 40 is formed at the interface between the bump 22 and the connection terminal 11.

### Third Embodiment

The bump 22 bonding step is carried out by bringing the bumps 22 into contact with the connection terminals 11 of the printed circuit board 10, after which the mounting head holding the semiconductor chip 20 is heated, whereby the bumps 22 formed on the electrodes 21 of the semiconductor chip 20 are fusion-bonded to the connection terminals 11 of the printed circuit board 10, in a state in which the bumps 22 are molten.

At this time, the mounting head, the semiconductor chip 20, the printed circuit board 10, and the stage on which the printed circuit board 10 is placed, all undergo thermal expansion; therefore, if the height of the mounting head is not adjusted, the distance between the semiconductor chip 20 and the printed circuit board 10 decreases with the thermal expansion, leading to the molten bumps 22 being crushed. Therefore, it is conceived that the bonding step of the bumps 22 is carried out while increasing the height of the mounting head in accordance with the thermal expansion of the mounting head, etc., such that the distance between the electrodes 21 and the connection terminals 11 does not change, so that pressing force from the semiconductor chip 20 and the printed circuit board 10 is not applied to the molten bumps 22.

In the third embodiment, in the bonding step of the bumps 22, instead of raising the height of the mounting head in accordance with the thermal expansion of the mounting head, etc., the height of the mounting head is raised to a prescribed height before the thermal expansion of the mounting head, etc., after which vibration is applied to the printed circuit board 10 or the semiconductor chip 20.

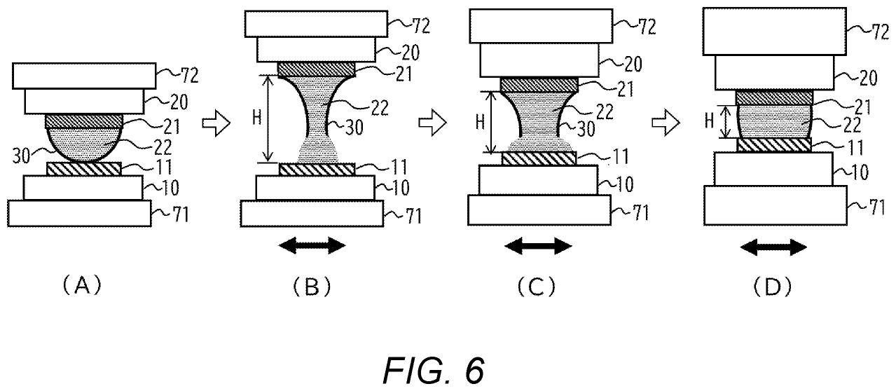

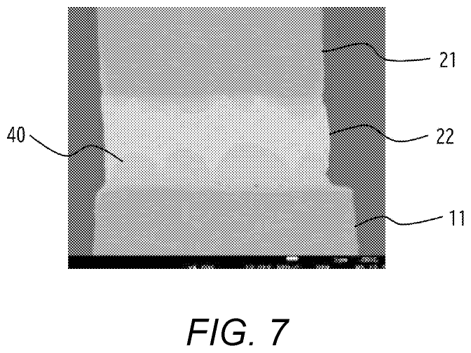

FIG. 6 is a diagram explaining the bonding step of the bumps 22 according to the third embodiment. The bonding step is carried out by a bonding device. In the illustrated embodiment, the bonding device includes a processing chamber in which the semiconductor chip 20 and the printed circuit board 10 are accommodated and the bonding step for bonding the bumps 22 to the connection terminals 11 is carried out, a stage 71 disposed within the processing chamber and on which the printed circuit board 10 is placed, a mounting head 72 disposed within the processing chamber and holding the semiconductor chip 20, an application unit or vibrator having a servo motor to generate the vibration applied to the printed circuit board 10 (the stage) or the semiconductor chip 20 (the mounting head), and an electronic controller operatively coupled to various components of the bonding device, such as the stage (an electronic actuator of the stage to change the height or position of the stage), the mounting head (an electronic actuator of the mounting head to change the height or position of the mounting head), the application unit (the servo motor), etc., to carry out the bonding step. The controller is configured by a general-purpose computer device, for example, and includes at least one processor having a CPU (Central Processing Unit) and a storage device or computer memory, and an interface for each device is included, as necessary. Thus, the operations of the bonding device for the bonding step described below are controlled and executed by the processing of the controller.

As shown in FIG. 6, the controller controls the electronic actuator of the mounting head or the stage such that the bumps 22 formed on the electrodes 21 of the semiconductor chip 20 are brought into contact with the connection terminals 11 of the printed circuit board 10 (step A), after which the controller controls a heater of the mounting head 72 holding the semiconductor chip 20 to melt the bump 22. In this state, the controller controls the mounting head 72 to raise the mounting head 72 to a prescribed height such that the distance H between the electrodes 21 and the connection terminals 11 is adjusted or increased to a prescribed distance under the condition that the bumps 22 do not separate from the connection terminals 11, after which the controller controls the servo motor of the application unit such that the application of the vibration to the stage 71 on which the printed circuit board 10 is placed is started (step B).

At this time, the molten bumps 22 flow due to the vibration applied to the stage 71 (the printed circuit board 10), whereby the oxide film 30 remaining on the surfaces of the bumps 22 in contact with the connection terminals 11 is broken by the flow pressure of the bumps 22, which exposes the true surfaces of the bumps 22, and the bumps 22 are wetted and spread over the surfaces of the connection terminals 11.

Subsequently, in a state in which the height of the mounting head 72 is maintained at the prescribed height, the controller controls the servo motor of the application unit such that the application of the vibration is continued while decreasing the distance H between the electrodes 21 and the connection terminals 11, as the mounting head 72, the semiconductor chip 20, the printed circuit board 10, and the stage 71 undergo thermal expansion (steps C and D). As a result, the molten bumps 22 are wetted and spread over the entire surface of the connection terminal 11, forming an intermetallic alloy at the interface between the bump 22 and the connection terminal 11.

FIG. 7 is a cross-sectional SEM photograph of a bonding portion of a bump according to an embodiment. As shown in FIG. 7, the molten bumps 22 are wetted and spread over the entire surface of the connection terminal 11, forming the intermetallic alloy 40 at the interface between the bump 22 and the connection terminal 11. As a result, it is possible to reduce the interfacial resistance between the bump 22 and the connection terminal 11.

In the third embodiment, the distance H between the electrodes 21 and the connection terminals 11 is adjusted or increased to the prescribed distance, and then the application of the vibration to the stage 71 (the printed circuit board 10) is started, whereby the vibration is applied to the elongated bumps 22, that is, to bumps 22 having a small contact surface with the connection terminals 11. As a result, the amplitude of the vibration applied to the stage 71 (the printed circuit board 10) can be decreased, so that a short circuit with the adjacent electrodes 21 can be prevented even if the bump 22 pitch narrows.

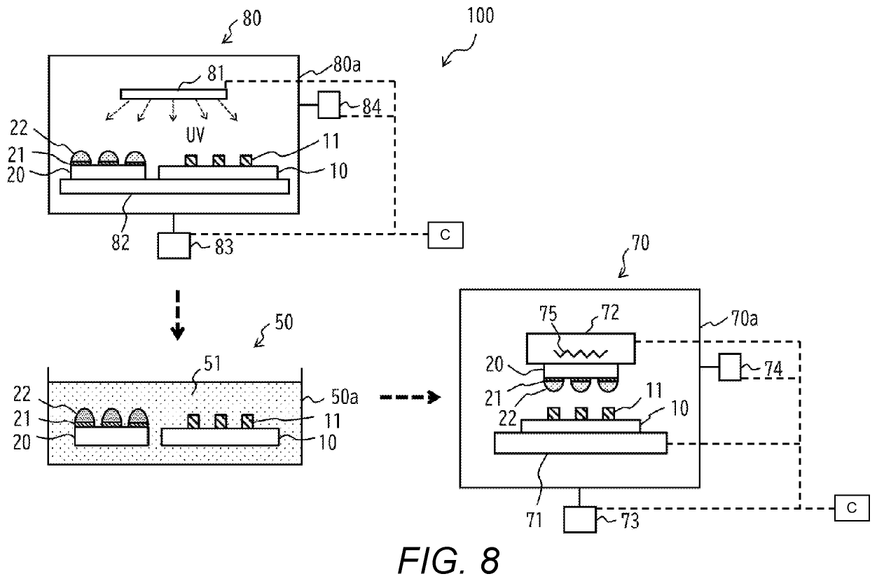

FIG. 8 is a cross-section diagram schematically showing a configuration of an electronic component mounting system according to one embodiment of the present disclosure. In the present embodiment, an example will be described in which bumps formed on electrodes (first electrode) of a semiconductor chip (first electronic component) are fusion-bonded to connection terminals (second electrode) of a printed circuit board (second electronic component). The semiconductor chip may be a plurality of semiconductor chips diced in a wafer state.

As shown in FIG. 8, an electronic component mounting system 100 according to the present embodiment is a device or system that bonds the bumps 22 formed on the electrodes 21 of the semiconductor chip 20 to the connection terminals 11 of the printed circuit board 10. The electronic component mounting system 100 includes the irradiation device 80, the etching device 50, and the bonding device 70. In the illustrated embodiment, the etching device 50 is equipped with a cleaning and drying device (not shown) that cleans and dries the semiconductor chip 20 and the printed circuit board 10 that have been etched. FIG. 8 illustrates detailed configurations of the irradiation device 80 shown in FIG. 2, the etching device 50 shown in FIG. 1A and the bonding device 70 shown in FIGS. 1C and 1D. Thus, the electronic component mounting system 100 can be utilized in a process according to the first embodiment.

The irradiation device 80 irradiates the surfaces of the semiconductor chip 20 and the printed circuit board 10 with ultraviolet rays (UV) to remove contaminants adhered to the surfaces of the semiconductor chip 20 and the printed circuit board 10.

The etching device 50 etches the semiconductor chip 20 and the printed circuit board 10 with an etching solution containing a weakly acidic organic acid such as citric acid to remove oxide film formed on the surfaces of the bumps 22 and the connection terminals 11.

The bonding device 70 accommodates the semiconductor chip 20 and the printed circuit board 10 that have been etched by the etching device 50, and, in a state in which inert gas is supplied thereto, bonds the bumps 22 formed on the electrodes 21 of the semiconductor chip 20 to the connection terminals 11 of the printed circuit board 10.

The electronic component mounting system 100 according to the present embodiment is able to etch the semiconductor chip (first electronic component) 20 and the printed circuit board (second electronic component) 10 with a weakly acidic organic acid such as citric acid using the etching device 50 before bonding the bumps 22 formed on the electrodes (first electrode) 21 of the semiconductor chip 20 to the connection terminals (second electrode) 11 of the printed circuit board 10 to remove oxide film (metal oxide film) formed on the surfaces of the bumps 22 and the connection terminals 11, thereby making it possible to carry out bump bonding in a state in which the metal oxide film is removed.

In the present embodiment, the metal oxide film is etched off using a weakly acidic organic acid; therefore, handling is easy, and it is not necessary to take measures against corrosion from carboxylic acid gas or against residues of carboxylic acid salt, so that it is possible to obtain highly-reliable fluxless bump bonding with a simple device, compared to conventional reduction processes of metal oxide film using carboxylic acid gas.

In addition, the irradiation device 80 irradiates the surfaces of the semiconductor chip 20 and the printed circuit board 10 with ultraviolet rays before etching off the metal oxide film to remove, in advance, contaminants adhered to the surfaces of the semiconductor chip 20 and the printed circuit board 10, whereby it is possible to remove the metal oxide film in a short period of time and to keep the etching solution clean.

Specific configurations of the irradiation device 80, the etching device 50, and the bonding device 70 will be described below with reference to FIG. 8.

### <Irradiation Device>

The irradiation device 80 comprises a chamber 80a that accommodates the semiconductor chip 20 and the printed circuit board 10, a vacuum pump 83 that exhausts the interior of the chamber 80a, a supply means or unit 84 that supplies inert gas such as nitrogen into the chamber 80a, an ultraviolet light source 81 that irradiates ultraviolet rays, and a stage 82 on which the semiconductor chip 20 and the printed circuit board 10 are placed. The ultraviolet light source 81 and the stage 82 are provided inside the chamber 80a. Furthermore, the irradiation device 80 includes an electronic controller C operatively coupled to various components of the irradiation device 80, such as the vacuum pump 83, the supply unit 84 (an electronic actuator for a valve of the supply unit 84), the ultraviolet light source 81 and the stage 82 (an electronic actuator of the stage 82 to change the height or position of the stage 82), etc. The controller C is configured by a general-purpose computer device, for example, and includes at least one processor having a CPU (Central Processing Unit) and a storage device or computer memory, and an interface for each device is included, as necessary. Thus, the operations of the irradiation device 80 described below are controlled and executed by the controller C.

The controller C controls the vacuum pump 83 to exhaust the interior of the chamber 80a with the vacuum pump 83. After exhausting the interior of the chamber 80a with the vacuum pump 83, the controller C controls the supply unit 84 to supply inert gas, such as nitrogen, into the chamber 80a by the supply unit 84. In a state in which the inert gas is supplied into the chamber 80a by the supply unit 84, the controller C controls the ultraviolet light source 81 such that the surfaces of the semiconductor chip 20 and the printed circuit board 10 are irradiated with ultraviolet rays from the ultraviolet light source 81. As a result, contaminants adhered to the surfaces of the semiconductor chip 20 and the printed circuit board 10 are removed. In the illustrated embodiment, the supply unit 84 includes a container or tank for storing the inert gas and the valve to control the supply of the inert gas to the chamber 80a.

A mercury lamp, a xenon lamp, an excimer lamp, etc., can be used as an ultraviolet light source 62. While the wavelength of the ultraviolet rays is not particularly limited, it is more preferable to use vacuum ultraviolet rays with a short wavelength and high energy (wavelength of less than or equal to 200 nm).

In addition, the irradiation device 80 may be an irradiation device that irradiates the surfaces of the semiconductor chip 20 and the printed circuit board 10 with plasma, instead of irradiating ultraviolet rays. In the illustrated embodiment, FIG. 8 illustrates detailed configurations of the irradiation device 80 shown in FIG. 2, and the irradiation device 80 shown in FIG. 8 can be utilized in the processes according to the first to the third embodiments.

### <Etching Device>

The etching device 50 comprises an etching tank 50a containing an aqueous solution (etching solution) 51 containing a weakly acidic organic acid such as citric acid. The semiconductor chip 20 and the printed circuit board 10 are immersed in the etching solution 51 in the etching tank 50a, whereby the oxide film formed on the surfaces of the bumps 22 and the connection terminals 11 is etched off.

The etching solution 51 is not particularly limited as long as the solution exhibits an etching action on oxide film of the bumps 22 and connection terminals 11, and weakly acidic organic acids can be used such as acetic acid, tartaric acid, malonic acid, succinic acid, and adipic acid, in addition to citric acid. In addition, the etching solution 51 may be a mixture of these organic acids.

The semiconductor chip 20 and the printed circuit board 10 that have been etched by the etching device 50 are cleaned and dried by a cleaning and drying device (not shown).

The etching device 50 may be an etching device that sprays the etching solution 51 as a mist onto the surfaces of the semiconductor chip 20 and the printed circuit board 10 instead of immersing the semiconductor chip 20 and the printed circuit board 10 in the etching solution 51. In the illustrated embodiment, FIG. 8 illustrates detailed configurations of the etching device 50 shown in FIG. 1A, and the etching device 50 shown in FIG. 8 can be utilized in the processes according to the first to the third embodiments.

### <Bonding Device>

The bonding device 70 comprises a chamber 70a that accommodates the semiconductor chip 20 and the printed circuit board 10, the stage 71 on which the printed circuit board 10 is placed, and the mounting head 72 that holds the semiconductor chip 20. The bonding device 70 also comprises a vacuum pump 73, and a supply unit 74 that supplies inert gas into the chamber 70a. In the illustrated embodiment, the supply unit 74 includes a container or tank for storing the inert gas and a valve to control the supply of the inert gas to the chamber 70a. Furthermore, the bonding device 70 includes an electronic controller C operatively coupled to various components of the bonding device 70, such as the vacuum pump 73, the supply unit 74 (an electronic actuator for the valve of the supply unit 74), the stage 71 (an electronic actuator of the stage 71 to change the height or position of the stage 71), the mounting head 72 (an electronic actuator of the mounting head 72 to change the height or position of the mounting head 72 or a heater 75 of the mounting head 72), etc. The controller C is configured by a general-purpose computer device, for example, and includes at least one processor having a CPU (Central Processing Unit) and a storage device or computer memory, and an interface for each device is included, as necessary. Thus, the operations of the bonding device 70 described below are controlled and executed by the controller C.

The mounting head 72 is disposed at a location facing the stage 71, and holds the semiconductor chip 20 in an inverted state (face down) such that the bumps 22 formed on the electrodes 21 of the semiconductor chip 20 face the connection terminals 11 of the printed circuit board 10. In addition, the mounting head 72 is provided with the heater 75 that heats the semiconductor chip 20.

The controller C controls the vacuum pump 73 to exhaust the interior of the chamber 70a with the vacuum pump 73. After being exhausted by the vacuum pump 73, the controller C controls the supply unit 74 to supply inert gas, such as nitrogen, into the chamber 70a by the supply unit 74. Specifically, the interior of the chamber 70a is brought to an inert gas atmosphere by supplying the inert gas into the chamber 70a from the container of the supply unit 74.

In a state in which the inert gas is supplied into the chamber 70a, the controller C controls the mounting head 72 such that the mounting head 72 holding the semiconductor chip 20 is lowered toward the printed circuit board 10, thereby pressing the bumps 22 of the semiconductor chip 20 against the connection terminals 11 of the printed circuit board 10. Subsequently, the controller C controls the mounting head 72 (the heater 75) such that the semiconductor chip 20 is heated with the heater 75 to a temperature at which the bumps 22 melt, thereby fusion-bonding the bumps 22 to the connection terminals 11 (refer to FIGS. 1C and 1D). In the illustrated embodiment, FIG. 8 illustrates detailed configurations of the bonding device 70 shown in FIGS. 1C and 1D, and the bonding device 70 shown in FIG. 8 can be utilized in the processes according to the first embodiment.

The bonding device 70 is not limited to the configuration described above; for example, a common configuration of a well-known flip-chip bonder may be employed.

The semiconductor chip 20 and the printed circuit board 10 that have been etched by the etching device 50 are, after cleaning and drying, preferably transported to the bonding device 70 in an atmosphere of inert gas such as nitrogen such that the surfaces of the bumps 22 and the connection terminals 11 are not re-oxidized during transport to the bonding device 70.

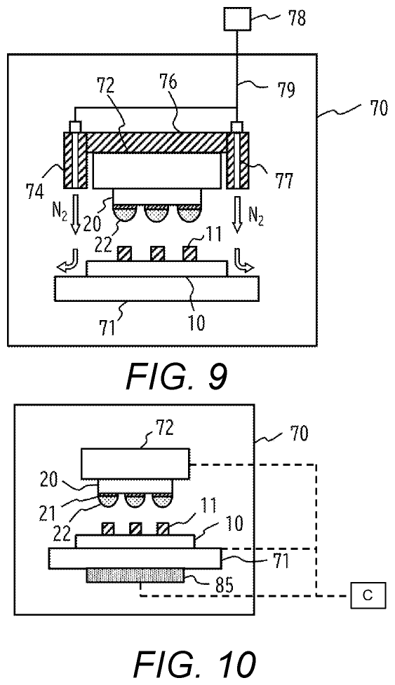

As shown in FIG. 9, the bonding device 70 may comprise a supply means or unit 76 that supplies inert gas, such as nitrogen, around the semiconductor chip 20 and the printed circuit board 10 when fusion-bonding the bumps 22 formed on the electrodes 21 of the semiconductor chip 20 to the connection terminals 11 of the printed circuit board 10.

The supply unit 76 includes a case that is attached to the mounting head 72 so as to surround the side surface of the mounting head 72. Through-holes 77 through which the inert gas passes is provided on the sides of the case of the supply unit 76. The supply unit 76 includes a storage chamber 78 that stores the inert gas and is connected to the through-holes 77 via piping 79. The inert gas is sprayed toward the stage 71 from the distal end portions of the through-holes 77. As a result, an air curtain is formed around the semiconductor chip 20 and the printed circuit board 10, which prevents intrusion of outside air. As a result, even if the interior of the bonding device 70 is not entirely filled with the inert gas, it is possible to prevent the surfaces of the bumps 22 and the connection terminals 11 from being oxidized. In FIG. 9, the bonding device 70 is illustrated without the vacuum pump 73, the heater 75 and the controller C for the sake of brevity, but can include the vacuum pump 73, the heater 75 and the controller C, as shown in FIG. 8. In this case, the controller C is further operatively connected to the supply unit 76 (an electronic actuator for a valve of the storage chamber 78) to supply the inert gas into the chamber 70a from the storage chamber 78.

In addition, as shown in FIG. 10, the bonding device 70 may further be provided with an application means unit 85 that applies, to the stage 71 on which the printed circuit board 10 is placed, vibration that causes relative displacement in a direction parallel to the interface between the bump 22 and the connection terminal 11. The controller C is further operatively coupled to the application unit 85 (a servo motor of the application unit 85) to apply vibration to the stage 71. In FIG. 10, the bonding device 70 is illustrated without the vacuum pump 73, the supply unit 74 or 76, and the heater 75 for the sake of brevity, but can include the vacuum pump 73, the supply unit 75 or 76 and the heater 75, as shown in FIG. 8 or 9. In the illustrated embodiment, the controller controls the electronic actuator of the mounting head 72 or the stage 71 such that the bumps 22 are brought into contact with the connection terminals 11. Then, the controller C controls the mounting head 72 (the heater 75) to melt the bump 22. In a state in which the bumps 22 are brought into contact with the connection terminals 11 and then molten, the controller C controls the application unit 85 (the servo motor) to apply vibration to the stage 71. The molten bumps 22 flow due to the vibration applied to the printed circuit board 10 placed on the stage 71, whereby the oxide film 30 remaining on the surface of the bumps 22 that have come in contact with the connection terminals 11 is broken by the flow pressure of the bumps 22, exposing the true surfaces of the bumps 22. As a result, it is possible to form an intermetallic compound at the interface between the bumps 22 and the connection terminal 11. The application unit 85 for applying vibration may apply the vibration to the mounting head 72 that holds the semiconductor chip 20. In the illustrated embodiment, the addition of vibration by the application unit 85 is be performed by the servo motor, but the application unit 85 can include any other type of vibration actuator, such as a piezoelectric actuator, an ultrasonic transducer, a linear actuator, or the like. In the illustrated embodiment, FIG. 10 illustrates detailed configurations of the bonding device 70, and the bonding device 70 shown in FIG. 10 can be utilized in the processes according to the second and third embodiments, as well as the first embodiment.

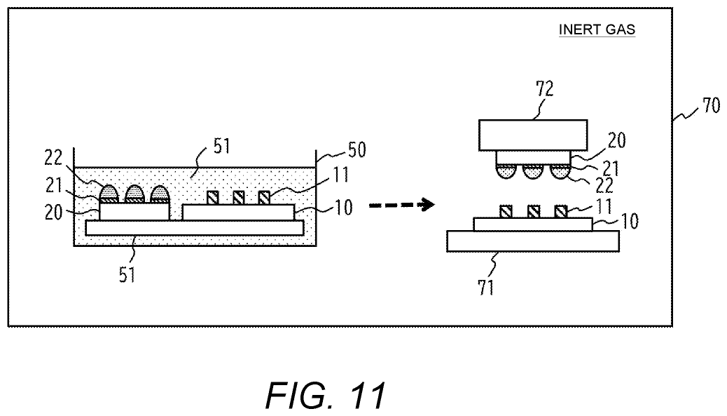

In addition, as shown in FIG. 11, the etching device 50 may be incorporated into the bonding device 70 together with the accompanying cleaning and drying device (not shown). In this case, the etching device 50 is disposed within a chamber of the bonding device 70. The semiconductor chip 20 and the printed circuit board 10 that have been etched are respectively transported by a transport mechanism (not shown). Then, the semiconductor chip 20 is held by the mounting head 72, while the printed circuit board 10 is placed on the stage 71.

If the conventional reduction process of metal oxide film using a carboxylic acid gas is carried out in a bonding device, the components in the bonding device may corrode, making it difficult to incorporate the process in the bonding device, but the present disclosure makes such an incorporation possible.

When using the etching device 50 to carry out etching of a plurality of the semiconductor chips 20 diced in a wafer state, etching, cleaning, and drying may be carried out on the plurality of the semiconductor chips 20 in the wafer state inside the bonding device 70. In this case, after the etching process and the cleaning and drying process are completed, each of the semiconductor chips 20 is picked up from the wafer and held by the mounting head 72 in an inverted state.

Note that it is not necessary for the electronic component mounting system 100 according to the present embodiment to be equipped with the irradiation device 80 if the amount of contaminants adhered to the surfaces of the semiconductor chip 20 and the printed circuit board 10 is of a degree that does not affect removal of the oxide film in the etching process of the oxide film formed on the surfaces of the bumps 22 and the connection terminals 11.

The present disclosure was described above with respect to preferred embodiments, but the descriptions are not limiting matters, and various modifications are, of course, possible.

What is claimed is:

1. An electronic component mounting method for bonding a bump formed on a first electrode of a first electronic component to a second electrode formed on a second electronic component, the method comprising:
etching the first electronic component and the second electronic component using a weakly acidic organic acid to remove an oxide film formed on surfaces of the second electrode and the bump; and
bonding the bump formed on the first electrode of the first electronic component to the second electrode formed on the second electronic component in a state in which the first electronic component and the second electronic component are accommodated in a bonding device after the etching, and inert gas is supplied to the bonding device.

2. The electronic component mounting method according to claim 1, further comprising
irradiating ultraviolet rays or plasma onto surfaces of the first electronic component and the second electronic component before the etching.

3. The electronic component mounting method according to claim 1, wherein
the weakly acidic organic acid is an organic acid selected from the group consisting of citric acid, acetic acid, tartaric acid, malonic acid, succinic acid, and adipic acid.

4. The electronic component mounting method according to claim 1, wherein
the bonding is carried out in a state in which the inert gas is supplied inside the bonding device around the first electronic component and the second electronic component.

5. The electronic component mounting method according to claim 1, wherein
the etching is executed inside the bonding device, and
the etching and the bonding are carried out in a state in which the bonding device is filled with the inert gas.

6. The electronic component mounting method according to claim 1, wherein
the bonding is carried out by bringing the bump formed on the first electrode into contact with the second electrode, and then, in a state in which the bump is in a molten state, applying to the first electronic component or the second electronic component vibration that causes relative displacement in a direction parallel to an interface between the bump and the second electrode.

7. The electronic component mounting method according to claim 6, wherein,
during the bonding, the vibration is applied to the first electronic component or the second electronic component while controlling a distance between the first electrode and the second electrode such that pressing force from the first electronic component and the second electronic component is not applied to the molten bump.

8. The electronic component mounting method according to claim 6, wherein,
during the bonding, vibration frequency of the vibration applied to the first electronic component or the second electronic component is in the range of 1/20 Hz to 50 Hz.

9. The electronic component mounting method according to claim 6, wherein,
during the bonding, amplitude of the vibration applied to the first electronic component or the second electronic component is greater than or equal to 1/20 of a width of the bump.

10. The electronic component mounting method according to claim 6, wherein the bonding includes
bringing the bump formed on the first electrode into contact with the second electrode,
adjusting a distance between the first electrode and the second electrode to a prescribed distance under the condition that the bump does not separate from the second electrode, in a state in which the bump is in a molten state,
starting application of the vibration to the first electronic component or the second electronic component, and
continuing the application of the vibration while decreasing the distance between the first electrode and the second electrode.

11. An electronic component mounting system for bonding a bump formed on a first electrode of a first electronic component to a second electrode formed on a second electronic component, the system comprising:
an etching device configured to etch the first electronic component and the second electronic component using a weakly acidic organic acid to remove an oxide film formed on surfaces of the second electrode and the bump; and
a bonding device configured to accommodate the first electronic component and the second electronic component that have been etched in the etching device, and configured to bond the bump formed on the first electrode of the first electronic component to the second electrode formed on the second electronic component in a state in which inert gas is supplied.

12. The electronic component mounting system according to claim 11, further comprising
an irradiation device configured to irradiate ultraviolet rays or plasma onto surfaces of the first electronic component and the second electronic component,
the first electronic component and the second electronic component irradiated by the irradiation device being configured to be etched with the weakly acidic organic acid in the etching device.

13. The electronic component mounting system according to claim 11, wherein
the weakly acidic organic acid is an organic acid selected from the group consisting of citric acid, acetic acid, tartaric acid, malonic acid, succinic acid, and adipic acid.

14. The electronic component mounting system according to claim 11, wherein
the bonding device has a supply unit configured to supply the inert gas around the first electronic component and the second electronic component when bonding the bump formed on the first electrode of the first electronic component to the second electrode formed on the second electronic component.

15. The electronic component mounting system according to claim 11, wherein
the etching device is incorporated in the bonding device, and
the bonding device has a filling unit configured to fill the bonding device with the inert gas.

16. The electronic component mounting system according to claim 11, wherein
the bonding device has an application unit configured to apply to the first electronic component or the second electronic component vibration that causes relative displacement in a direction parallel to an interface between the bump and the second electrode, in a state in which the bump is molten.

17. The electronic component mounting system according to claim 16, wherein
the vibration is applied by the application unit to the first electronic component or the second electronic component while controlling a distance between the first electrode and the second electrode such that substantial pressing force from the first electronic component and the second electronic component is not applied to the molten bump.

18. The electronic component mounting system according to claim 16, wherein
vibration frequency of the vibration applied by the application unit to the first electronic component or the second electronic component is in the range of 1/20 Hz to 50 Hz.

19. The electronic component mounting system according to claim 16, wherein
amplitude of the vibration applied by the application unit to the first electronic component or the second electronic component is greater than or equal to 1/20 of a width of the bump.

20. An electronic component mounting method for bonding a bump formed on a first electrode of a first electronic component to a second electrode formed on a second electronic component, the method comprising:
etching the second electronic component using a weakly acidic organic acid to remove an oxide film formed on a surface of the second electrode;
accommodating the first electronic component and the second electronic component in a bonding device after the etching; and
bonding the bump formed on the first electrode of the first electronic component to the second electrode formed on the second electronic component in a state in which inert gas is supplied to the bonding device,
the bonding being carried out by bringing the bump formed on the first electrode into contact with the second electrode, and then, in a state in which the bump is in a molten state, applying to the first electronic component or the second electronic component vibration that causes relative displacement in a direction parallel to an interface between the bump and the second electrode.

21. The electronic component mounting method according to claim 20, wherein,
during the bonding, the vibration is applied to the first electronic component or the second electronic component while controlling a distance between the first electrode and the second electrode such that pressing force from the first electronic component and the second electronic component is not applied to the molten bump.

22. The electronic component mounting method according to claim 20, wherein,
during the bonding, vibration frequency of the vibration applied to the first electronic component or the second electronic component is in the range of 1/20 Hz to 50 Hz.

23. The electronic component mounting method according to claim 20, wherein,
during the bonding, amplitude of the vibration applied to the first electronic component or the second electronic component is greater than or equal to 1/20 of a width of the bump.
